(19) United States
(12) Patent Application Publication
(10) Pub. No.: US 2025/0295018 A1
(43) Pub. Date: Sep. 18, 2025

(54) DISPLAY DEVICE AND OPTICAL DEVICE

(71) Applicant: Samsung Display Co., LTD., Yongin-si (KR)

(72) Inventors: Young Gu KIM, Yongin-si (KR); Seung Beom PARK, Yongin-si (KR); Yun JANG, Yongin-si (KR); Baek Kyun JEON, Yongin-si (KR)

(73) Assignee: Samsung Display Co., LTD., Yongin-si (KR)

(21) Appl. No.: 18/945,944

(22) Filed: Nov. 13, 2024

(30) Foreign Application Priority Data
Mar. 14, 2024 (KR) 10-2024-0035875

(51) Int. Cl. H10K 59/80; G02B 5/30

(52) U.S. Cl. CPC H10K 59/8793; G02B 5/3058; G02B 5/3083

(57) ABSTRACT

A display device and an optical device are provided. The display device includes a display element layer disposed on a substrate, the display element layer including a first electrode, a light emitting layer, and a second electrode, a retardation layer disposed on the display element layer, the retardation layer including at least a capping layer, and a wire grid polarizer disposed on the retardation layer, the wire grid polarizer including a wire grid pattern in which a metal pattern and a grid pattern are stacked each other, the metal pattern is disposed on the capping layer, and has a thickness in a range of about 3 nm to about 7 nm.

### CROSS-REFERENCE TO RELATED APPLICATION(S)

This application claims priority to and benefits of Korean Patent Application No. 10-2024-0035875 under 35 U.S.C. § 119 filed on Mar. 14, 2024 in the Korean Intellectual Property Office, the entire contents of which are incorporated herein by reference.

### BACKGROUND

### 1. Technical Field

The disclosure relates to a display device and an optical device.

### 2. Description of the Related Art

A head mounted display (HMD) is an image display device that is worn on a user's head in the form of glasses or helmets to form a focus at a close distance in front of the user's eyes. The head mounted display may implement virtual reality (VR) or augmented reality (AR).

The head mounted display magnifies an image displayed on a small display device by using a plurality of lenses, and displays the magnified image. Therefore, the display device applied to the head mounted display needs to provide high-resolution images, for example, images with a resolution of 3000 PPI (Pixels Per Inch) or higher. To this end, an organic light emitting diode on silicon (OLEDoS), which is a high-resolution small organic light emitting display device, is used as the display device applied to the head mounted display. The OLEDoS is an image display device in which an organic light emitting diode (OLED) is disposed on a semiconductor wafer substrate on which a complementary metal oxide semiconductor (CMOS) is disposed.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a display device and an optical device capable of improving the adhesive strength of a wire grid polarizer.

However, aspects of the disclosure are not restricted to the ones set forth herein. The above and other aspects of the disclosure will become more apparent to one of ordinary skill in the art to which the disclosure pertains by referencing the detailed description of the disclosure given below.

According to an aspect of the disclosure, a display device may include a display element layer disposed on a substrate, the display element layer comprising a first electrode, a light emitting layer, and a second electrode; a retardation layer disposed on the display element layer, the retardation layer comprising at least a capping layer; and a wire grid polarizer disposed on the retardation layer, the wire grid polarizer comprising a wire grid pattern in which a metal pattern and a grid pattern are stacked each other, wherein the metal pattern is disposed on the capping layer, and has a thickness in a range of about of 3 nm to about 7 nm.

In an embodiment, the capping layer may include any one of silicon nitride, silicon oxide, or silicon oxynitride.

In an embodiment, the metal pattern may include any one of titanium (Ti), chromium (Cr), nickel (Ni), tantalum (Ta), or tungsten (W).

In an embodiment, the grid pattern may be disposed on the metal pattern, and a thickness of the grid pattern may be greater than a thickness of the metal pattern.

In an embodiment, a width of the grid pattern may be equal to a width of the metal pattern.

In an embodiment, a width of a lower surface of the metal pattern may be greater than a width of an upper surface of the metal pattern.

In an embodiment, the width of the upper surface of the metal pattern may be equal to a width of the grid pattern.

In an embodiment, a width of the metal pattern may gradually increase from an upper surface to a lower surface of the metal pattern.

In an embodiment, a side surface of the metal pattern may have an inclination, and an interior angle formed between the side surface of the metal pattern and a lower surface of the metal pattern may be greater than or equal to about 60 degrees and less than about 90 degrees.

In an embodiment, the display device may further comprise a planarization layer disposed on the wire grid polarizer, wherein the wire grid polarizer comprises an air layer disposed in an area partitioned by the capping layer, the wire grid pattern, and the planarization layer.

According to an aspect of the disclosure, a display device may include a display element layer disposed on a substrate, the display element layer comprising a first electrode, a light emitting layer, and a second electrode; a retardation layer disposed on the display element layer, the retardation layer comprising at least a capping layer; and a wire grid polarizer disposed on the retardation layer, the wire grid polarizer comprising a wire grid pattern in which a first metal pattern, a second metal pattern, and a grid pattern are stacked each other, wherein the first metal pattern is disposed on the capping layer, the second metal pattern is disposed on the first metal pattern, and the grid pattern is disposed on the second metal pattern.

In an embodiment, the capping layer may include any one of silicon nitride, silicon oxide, or silicon oxynitride.

In an embodiment, the first metal pattern and the second metal pattern may include different materials.

In an embodiment, each of the first metal pattern and the second metal pattern may include any one of titanium (Ti), chromium (Cr), nickel (Ni), tantalum (Ta), or tungsten (W).

In an embodiment, a thickness of the first metal pattern and a thickness of the second metal pattern may be different from each other.

In an embodiment, the thickness of the first metal pattern may be greater than the thickness of the second metal pattern.

According to an aspect of the disclosure, an optical device may include a display device; and an optical path changing member disposed on the display device, wherein the display device comprises a display element layer disposed on a substrate, the display element layer comprising a first electrode, a light emitting layer, and a second electrode; a retardation layer disposed on the display element layer, the retardation layer comprising at least a capping layer; and a wire grid polarizer disposed on the retardation layer, the wire grid polarizer comprising a wire grid pattern in which a metal pattern and a grid pattern are stacked each other, wherein the metal pattern is disposed on the capping layer, and has a thickness in a range of about 3 nm to about 7 nm.

In an embodiment, the capping layer may include any one of silicon nitride, silicon oxide, or silicon oxynitride.

In an embodiment, a width of the metal pattern may gradually increase from an upper surface to a lower surface of the metal pattern.

In an embodiment, the metal pattern may comprise a first metal pattern disposed on the capping layer and a second metal pattern disposed on the first metal pattern, and the grid pattern may be disposed on the second metal pattern.

The display device and the optical device according to an embodiment may improve the adhesive strength between a retardation layer and the wire grid polarizer and thus may prevent film lifting defects from occurring.

However, effects according to the embodiments of the disclosure are not limited to those described above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is an exploded schematic perspective view showing a display device according to an embodiment;

FIG. 2 is a block diagram illustrating a display device according to an embodiment;

FIG. 3 is a schematic diagram of an equivalent circuit of a first pixel according to an embodiment;

FIG. 4 is a plan diagram illustrating an example of a display panel according to an embodiment;

FIG. 5 is a plan diagram showing embodiments of the display area of FIG. 4;

FIG. 6 is a schematic cross-sectional view illustrating an example of the display panel 100 taken along line X-X′ of FIG. 5;

FIG. 7 is an enlarged schematic view of area A of FIG. 6;

FIG. 8 is a schematic cross-sectional view showing another example of a display panel according to an embodiment;

FIG. 9 is an enlarged schematic view of area B of FIG. 8;

FIG. 10 is a schematic cross-sectional view showing another example of a display panel according to an embodiment;

FIG. 11 is an enlarged schematic view of area C of FIG. 10;

FIG. 12 is a schematic plan view schematically showing a wire grid pattern;

FIG. 13 is an enlarged schematic view of area D of FIG. 11;

FIG. 14 is a schematic cross-sectional view showing an example of a display panel according to an embodiment;

FIG. 15 is a schematic cross-sectional view showing an example of a display panel according to an embodiment;

FIG. 16 is a schematic cross-sectional view showing an example of a display panel according to an embodiment;

FIG. 17 is an image of the substrate after the crosscut adhesive strength test according to Comparative Example 1;

FIG. 18 is an image of the substrate after the crosscut adhesive strength test according to Example 1;

FIG. 19 is a graph illustrating the crosscut adhesive strength according to the thickness of the titanium layer;

FIG. 20 is a graph illustrating the transmittance of the substrate according to the thickness of the titanium layer;

FIG. 21 is an image of a display panel manufactured according to Comparative Example 2;

FIG. 22 is an image of a display panel manufactured according to Example 3;

FIG. 23 is a schematic perspective view illustrating a head mounted display according to an embodiment;

FIG. 24 is an exploded schematic perspective view illustrating an example of the head mounted display of FIG. 23; and

FIG. 25 is a schematic perspective view illustrating a head mounted display according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will also be understood that when a layer is referred to as being “on” another layer or substrate, it can be directly on the other layer or substrate, or intervening layers may also be present. The same reference numbers indicate the same components throughout the specification.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

Each of the features of the various embodiments may be combined or combined with each other, in part or in whole. Each embodiment may be implemented independently of each other or may be implemented together.

Hereinafter, embodiments will be described with reference to the accompanying drawings.

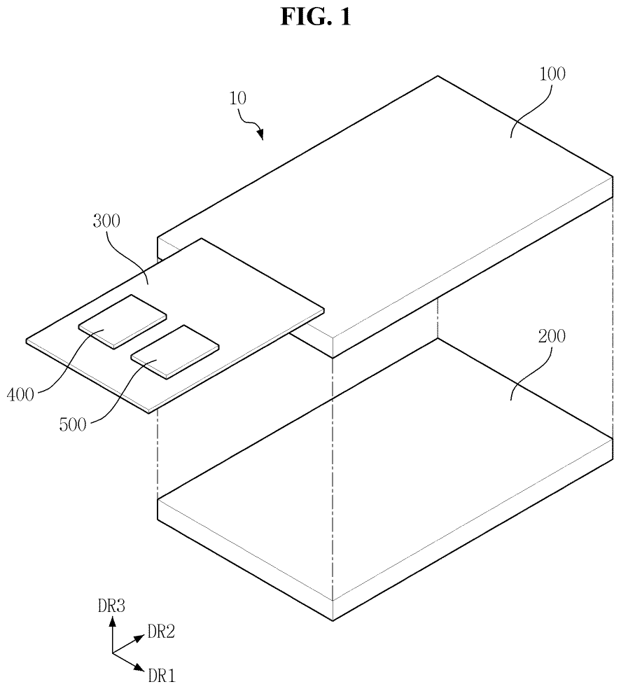

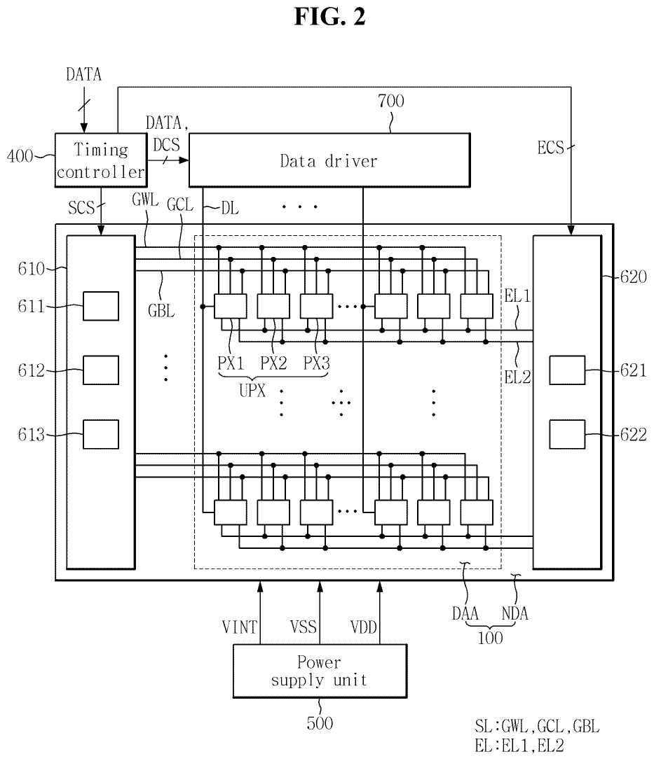

FIG. 1 is an exploded schematic perspective view showing a display device according to an embodiment. FIG. 2 is a block diagram illustrating a display device according to an embodiment.

Referring to FIGS. 1 and 2, a display device 10 according to an embodiment may be a device displaying a moving image or a still image. The display device 10 according to an embodiment may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like within the spirit and the scope of the disclosure. For example, the display device 10 according to an embodiment may be applied as a display unit of a television, a laptop, a monitor, a billboard, or an Internet-of-Things (IoT) terminal. By way of example, the display device 10 according to an embodiment may be applied to a smart watch, a watch phone, a head mounted display (HMD) for implementing virtual reality and augmented reality, and the like within the spirit and the scope of the disclosure.

The display device 10 according to an embodiment may include a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a selectable curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the embodiment is not limited thereto.

The display panel 100 may include a display area DAA displaying an image and a non-display area NDA not displaying an image as shown in FIG. 2.

The display area DAA may include a plurality of pixels PX, a plurality of scan lines SL, a plurality of emission control lines EL, and a plurality of data lines DL.

The plurality of pixels PX may be arranged or disposed in a matrix form in the first direction DR1 and the second direction DR2. The plurality of scan lines SL and the plurality of emission control lines EL may extend in the first direction DR1, while being disposed in the second direction DR2. The plurality of data lines DL may extend in the second direction DR2, while being disposed in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

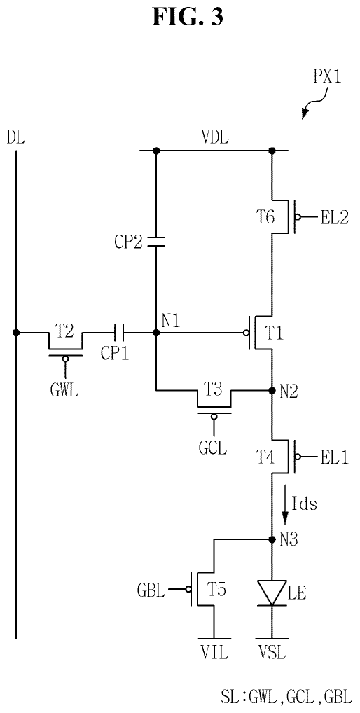

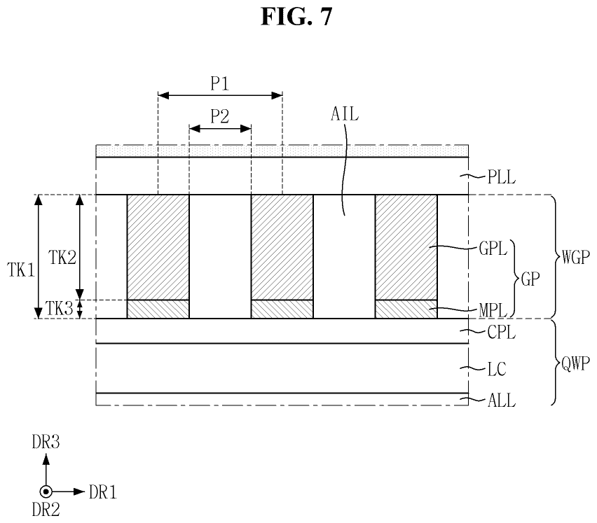

Each of a plurality of unit pixels UPX may include a plurality of pixels PX1, PX2, and PX3. The plurality of pixels PX1, PX2, and PX3 may include a plurality of pixel transistors as shown in FIG. 3, and the plurality of pixel transistors are formed through a semiconductor process and may be disposed on a semiconductor substrate SSUB (see FIG. 7). For example, the plurality of pixel transistors of a data driver 700 may be formed of complementary metal oxide semiconductor (CMOS).

Each of the plurality of pixels PX1, PX2, and PX3 may be connected to any one of the plurality of write scan lines GWL, any one of the plurality of control scan lines GCL, any one of the plurality of bias scan lines GBL, any one of the plurality of first emission control lines EL1, any one of the plurality of second emission control lines EL2, and any one of the plurality of data lines DL. Each of the plurality of pixels PX1, PX2, and PX3 may receive a data voltage of the data line DL in response to a write scan signal of the write scan line GWL, and emit light from the light emitting element according to the data voltage.

The non-display area NDA may include a scan driver 610, an emission driver 620, and the data driver 700.

The scan driver 610 may include a plurality of scan transistors, and the emission driver 620 may include a plurality of light emitting transistors. The plurality of scan transistors and the plurality of light emitting transistors may be formed on the semiconductor substrate SSUB (see FIG. 7) through a semiconductor process. For example, the plurality of scan transistors and the plurality of light emitting transistors may be formed of CMOS. Although it is illustrated in FIG. 2 that the scan driver 610 is disposed on the left side of the display area DAA and the emission driver 620 is disposed on the right side of the display area DAA, the embodiment is not limited thereto. For example, the scan driver 610 and the emission driver 620 may be disposed on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 may include a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

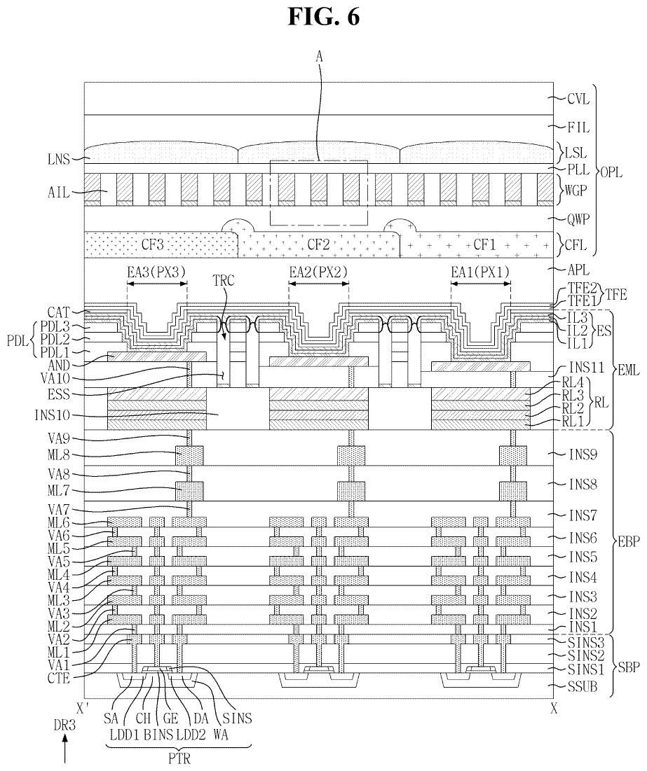

The data driver 700 may include a plurality of data transistors, and the plurality of data transistors may be formed on the semiconductor substrate SSUB (see FIG. 6) through a semiconductor process. For example, the plurality of data transistors may be formed of CMOS.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. For example, the pixels PX1, PX2, and PX3 are selected by the write scan signal of the scan driver 610, and data voltages may be supplied to the selected pixels PX1, PX2, and PX3.

The heat dissipation layer 200 may overlap the display panel 100 in a third direction DR3, which is the thickness direction of the display panel 100. The heat dissipation layer 200 may be disposed on one surface or a surface of the display panel 100, for example, on the rear surface thereof. The heat dissipation layer 200 may serve or function to dissipate heat generated from the display panel 100. The heat dissipation layer 200 may include a metal layer such as graphite, silver (Ag), copper (Cu), or aluminum (Al) having high thermal conductivity.

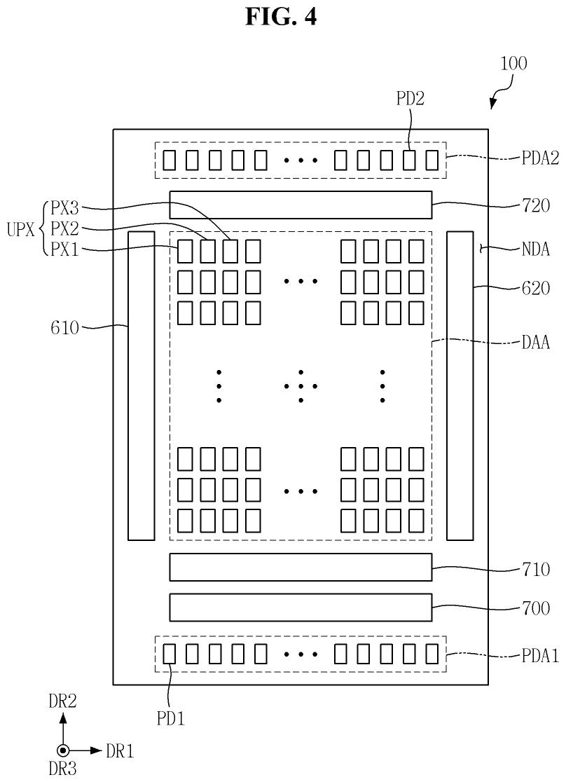

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. For example, one end of the circuit board 300 may be disposed on the rear surface of the display panel 100 and/or the rear surface of the heat dissipation layer 200. One end of the circuit board 300 may be an opposite end of the other end of the circuit board 300 connected to the plurality of first pads PD1 (see FIG. 4) of the first pad portion PDA1 (see FIG. 4) of the display panel 100 by using a conductive adhesive member.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface or a surface of the circuit board 300. For example, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

By way of example, each of the timing control circuit 400 and the power supply circuit 500 may be disposed in the non-display area NDA of the display panel 100, similarly to the scan driver 610, the emission driver 620, and the data driver 700. For example, the timing control circuit 400 may include a plurality of timing transistors, and each power supply circuit 500 may include a plurality of power transistors. The plurality of timing transistors and the plurality of power transistors may be formed on a semiconductor substrate SSUB (see FIG. 7) through a semiconductor process. For example, the plurality of timing transistors and the plurality of power transistors may be formed of CMOS. Each of the timing control circuit 400 and the power supply circuit 500 may be disposed between the data driver 700 and the first pad portion PDA1 (see FIG. 4).

FIG. 3 is a schematic diagram of an equivalent circuit of a sub-pixel according to an embodiment.

Referring to FIG. 3, a first pixel PX1 may be connected to the write scan line GWL, the control scan line GCL, the bias scan line GBL, the first emission control line EL1, the second emission control line EL2, and the data line DL. The first pixel PX1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. For example, the first driving voltage line VSL may be a low potential voltage line, the second driving voltage line VDL may be a high potential voltage line, and the third driving voltage line VIL may be an initialization voltage line. For example, the first driving voltage VSS may be lower than the third driving voltage VINT. The second driving voltage VDD may be higher than the third driving voltage VINT.

The first pixel PX1 may include a plurality of transistors T1 to T6, a light emitting element LE, a first capacitor CP1, and a second capacitor CP2.

The light emitting element LE emits light in response to a driving current Ids flowing through the channel of the first transistor T1. The emission amount of the light emitting element LE may be proportional to the driving current Ids. The light emitting element LE may be disposed between the fourth transistor T4 and the first driving voltage line VSL. The first electrode of the light emitting element LE may be connected to the drain electrode of the fourth transistor T4, and the second electrode thereof may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but the embodiment is not limited thereto. For example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current Ids (hereinafter referred to as a “driving current”) flowing between the source electrode and the drain electrode thereof according to a voltage applied to the gate electrode thereof. The first transistor T1 may include a gate electrode connected to a first node N1, a source electrode connected to the drain electrode of the sixth transistor T6, and a drain electrode connected to a second node N2.

The second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

The third transistor T3 may be disposed between the first node N1 and the second node N2. The third transistor T3 is turned on by the write control signal of the write control line GCL to connect the first node N1 to the second node N2. For this reason, since the gate electrode and the source electrode of the first transistor T1 are connected, the first transistor T1 may operate like a diode. The third transistor T3 may include a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light emitting element LE. The fourth transistor T4 may include a gate electrode connected to the first emission control line EL1, a source electrode connected to the second node N2, and a drain electrode connected to the third node N3.

The fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be formed between the first node N1 and the drain electrode of the second transistor T2. The first capacitor CP1 may include one electrode connected to the drain electrode of the second transistor T2 and the other electrode connected to the first node N1.

The second capacitor CP2 may be formed between the gate electrode of the first transistor T1 and the second driving voltage line VDL. The second capacitor CP2 may include one electrode connected to the gate electrode of the first transistor T1 and the other electrode connected to the second driving voltage line VDL.

The first node N1 may be a junction between the gate electrode of the first transistor T1, the drain electrode of the third transistor T3, the other electrode of the first capacitor CP1, and the one electrode of the second capacitor CP2. The second node N2 may be a junction between the drain electrode of the first transistor T1, the source electrode of the third transistor T3, and the source electrode of the fourth transistor T4. The third node N3 may be a junction between the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the embodiment is not limited thereto. Each of the first to sixth transistors T1 to T6 may be an N-type MOSFET. By way of example, some of the first to sixth transistors T1 to T6 may be P-type MOSFETs, and each of the remaining transistors may be an N-type MOSFET.

Although it is illustrated in FIG. 3 that the first pixel PX1 may include the six transistors T1 to T6 and the two capacitors C1 and C2, it should be noted that the equivalent circuit diagram of the first pixel PX1 is not limited to the example shown in FIG. 3. For example, the number of the transistors and the number of the capacitors of the first pixel PX1 are not limited to the example shown in FIG. 3.

The equivalent circuit diagram of a second pixel PX2 and the equivalent circuit diagram of a third pixel PX3 may be substantially the same as the equivalent circuit diagram of the first pixel PX1 described in conjunction with FIG. 3. Thus, in the specification, description of the equivalent circuit diagram of the second pixel PX2 and the equivalent circuit diagram of the third pixel PX3 will be omitted.

FIG. 4 is a plan diagram illustrating an example of a display panel according to an embodiment.

Referring to FIG. 4, the display area DAA of the display panel 100 according to an embodiment may include the plurality of pixels PX arranged or disposed in a matrix form. The non-display area NDA of the display panel 100 according to an embodiment may include the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side or a side of the display area DAA in the first direction DR1, and the emission driver 620 may be disposed on the other side of the display area DAA in the first direction DR1. For example, the scan driver 610 may be disposed on the left side of the display area DAA, and the emission driver 620 may be disposed on the right side of the display area DAA. However, the embodiment is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side or a side of the display area DAA in the second direction DR2.

The first pad portion PDA1 may be disposed outside the data driver 700 in the second direction DR2. For example, the first pad portion PDA1 may be disposed closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side or a side of the display area DAA in the second direction DR2. For example, the first distribution circuit 710 may be disposed on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. For example, the second distribution circuit 720 may be disposed on the upper side of the display area DAA.

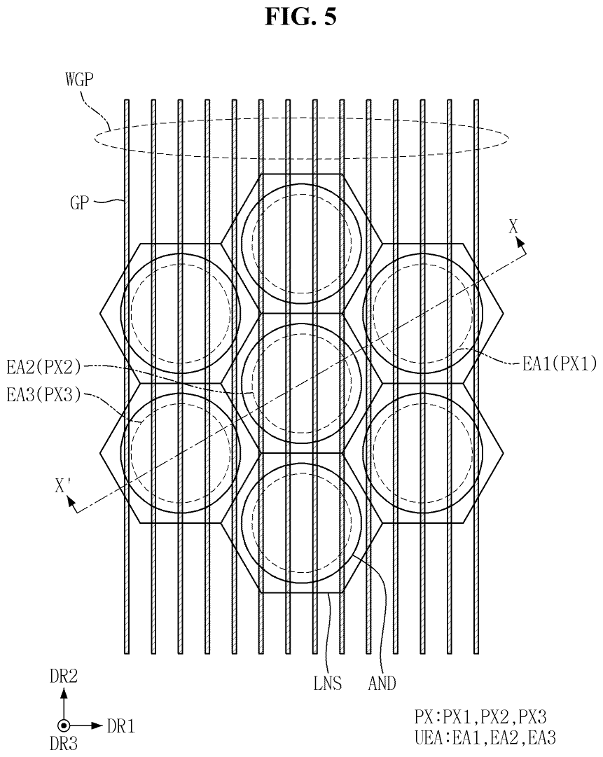

FIG. 5 is a plan diagram showing embodiments of the display area of FIG. 4.

Referring to FIG. 5, each of the plurality of unit pixels UPX may include a first emission area EA1 as an emission area of the first pixel PX1, a second emission area EA2 as an emission area of the second pixel PX2, and a third emission area EA3 as an emission area of the third pixel PX3. In other words, the unit pixel UPX may include a unit emission area, and the unit emission area UEA may include the first emission area EA1, the second emission area EA2, and the third emission area EA3 described above.

Each of the plurality of pixels PX may include a first emission area EA1 as an emission area of the first pixel PX1, a second emission area EA2 as an emission area of the second pixel PX2, and a third emission area EA3 as an emission area of the third pixel PX3.

Each of the first emission area EA1, the second emission area EA2, and the third emission area EA3 may have a polygonal, circular, elliptical, or irregular planar shape, but the shape of each of the emission areas EA1, EA2, and EA3 is not limited thereto.

The maximum length of the first emission area EA1 in the first direction DR1 may be smaller than the maximum length of the second emission area EA2 in the first direction DR1 and the maximum length of the third emission area EA3 in the first direction DR1. The maximum length of the second emission area EA2 in the first direction DR1 and the maximum length of the third emission area EA3 in the first direction DR1 may be substantially the same.

The maximum length of the first emission area EA1 in the second direction DR2 may be greater than the maximum length of the second emission area EA2 in the second direction DR2 and the maximum length of the third emission area EA3 in the second direction DR2. The maximum length of the second emission area EA2 in the second direction DR2 may be greater than the maximum length of the third emission area EA3 in the second direction DR2. The maximum length of the first emission area EA1 in the second direction DR2 may be smaller than the maximum length of the second emission area EA2 in the second direction DR2.

The first emission area EA1, the second emission area EA2, and the third emission area EA3 may have, in plan view, a hexagonal shape formed of six straight lines as shown in FIG. 5, but the embodiment is not limited thereto. The first emission area EA1, the second emission area EA2, and the third emission area EA3 may have a polygonal shape other than a hexagon, a circular shape, an elliptical shape, or an atypical shape in plan view.

As shown in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. The second emission area EA2 and the third emission area EA3 may be adjacent to each other in the second direction DR2. The area of the first emission area EA1, the area of the second emission area EA2, and the area of the third emission area EA3 may be different.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may be a wavelength band of light whose main peak wavelength is in the range of about 380 nm to about 480 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

It is described in FIG. 5 that each of the plurality of pixels PX may include three emission areas EA1, EA2, and EA3, but the embodiment is not limited thereto. For example, each of the plurality of pixels PX may include four emission areas.

The layout of the emission areas of the plurality of pixels PX is not limited to that illustrated in FIG. 5. For example, the emission areas of the plurality of pixels PX may be disposed in a stripe structure in which the emission areas are arranged or disposed in the first direction DR1, a PENTILE™ structure in which the emission areas are arranged or disposed in a diamond shape, or a hexagonal structure in which the emission areas having, in plan view, a hexagonal shape are arranged or disposed side by side as shown in FIG. 6.

FIG. 6 is a schematic cross-sectional view illustrating an example of the display panel 100 taken along line X-X′ of FIG. 5. FIG. 7 is an enlarged schematic view of area A of FIG. 6.

Referring to FIGS. 6 and 7, the display panel 100 may include a semiconductor backplane SBP, a light emitting element backplane EBP, a display element layer EML, an encapsulation layer TFE, and an optical layer OPL. The semiconductor backplane SBP and light emitting element backplane EBP may be referred to as substrates.

The semiconductor backplane SBP may include the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 4.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. For example, in case that the first type impurity is a p-type impurity, the second type impurity may be an n-type impurity. By way of example, in case that the first type impurity is an n-type impurity, the second type impurity may be a p-type impurity.

Each of the plurality of well regions WA may include a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side or a side of the gate electrode GE, and the drain region SA may be disposed on the other side of the gate electrode GE.

Each of the plurality of well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be prevented.

A first semiconductor insulating film SINS1 may be disposed on the semiconductor substrate SSUB. The first semiconductor insulating film SINS1 may be formed of silicon carbonitride (SiCN) or a silicon oxide (SiOₓ)-based inorganic film, but the embodiment is not limited thereto.

A second semiconductor insulating film SINS2 may be disposed on the first semiconductor insulating film SINS1. The second semiconductor insulating film SINS2 may be formed of a silicon oxide (SiOₓ)-based inorganic film, but the embodiment is not limited thereto.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through holes penetrating the first semiconductor insulating film SINS1 and the second semiconductor insulating film INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3. The third semiconductor insulating film SINS3 may be formed of a silicon oxide (SiOₓ)-based inorganic film, but the embodiment is not limited thereto.

The semiconductor substrate SSUB may be replaced with a glass substrate or a polymer resin substrate such as polyimide. For example, thin film transistors may be disposed on the glass substrate or the polymer resin substrate. The glass substrate may be a rigid substrate that does not bend, and the polymer resin substrate may be a flexible substrate that can be bent or curved.

The light emitting element backplane EBP may include a plurality of conductive layers ML1 to ML8, a plurality of vias VA1 to VA9, and a plurality of insulating films INS1 to INS9. The light emitting element backplane EBP may include a plurality of insulating films INS1 to INS11 disposed between the first to eighth conductive layers ML1 to ML8.

The first to eighth conductive layers ML1 to ML8 may serve to connect the plurality of contact terminals CTE exposed from the semiconductor backplane SBP to thereby implement the circuit of the first pixel PX1 shown in FIG. 4. For example, the first to sixth transistors T1 to T6 may be formed on the semiconductor backplane SBP, and the connection of the first to sixth transistors T1 to T6 and the first and second capacitors C1 and C2 may be accomplished through the first to eighth conductive layers ML1 to ML8. The connection between the drain region corresponding to the drain electrode of the fourth transistor T4, the source region corresponding to the source electrode of the fifth transistor T5, and the first electrode of the light emitting element LE may be also accomplished through the first to eighth conductive layers ML1 to ML8.

The first insulating film INS1 may be disposed on the semiconductor backplane SBP.

Each of the first vias VA1 may penetrate the first insulating film INS1 to be connected to the contact terminal CTE exposed from the semiconductor backplane SBP. Each of the first conductive layers ML1 may be disposed on the first insulating film INS1 and may be connected to the first via VAL.

The second insulating film INS2 may be disposed on the first insulating film INS1 and the first conductive layers ML1. Each of the second vias VA2 may penetrate the second insulating film INS2 and be connected to the exposed first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate the third insulating film INS3 and be connected to the exposed second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate the fourth insulating film INS4 and be connected to the exposed third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate the fifth insulating film INS5 and be connected to the exposed fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate the sixth insulating film INS6 and be connected to the exposed fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate the seventh insulating film INS7 and be connected to the exposed sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate the eighth insulating film INS8 and be connected to the exposed seventh conductive layer ML7. Each of the eighth conductive layers ML8 may be disposed on the eighth insulating film INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may be made of substantially the same material. First to eighth insulating films INS1 to INS8 may be formed of a silicon oxide (SiOₓ)-based inorganic film, but the embodiment is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be larger than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be larger than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be about 1360 Å; the thickness of each of the second conductive layer ML2, the third conductive layer ML3, the fourth conductive layer ML4, the fifth conductive layer ML5, and the sixth conductive layer ML6 may be about 1440 Å; and the thickness of each of the first via VA1, the second via VA2, the third via VA3, the fourth via VA4, the fifth via VA5, and the sixth via VA6 may be about 1150 Å.

The thickness of each of the seventh conductive layer ML7 and the eighth conductive layer ML8 may be larger than the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the thickness of the eighth conductive layer ML8 may be larger than the thickness of the seventh via VA7 and the thickness of the eighth via VA8, respectively. The thickness of each of the seventh via VA7 and the eighth via VA8 may be larger than the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be about 9000 Å. The thickness of each of the seventh via VA7 and the eighth via VA8 may be about 6000 Å.

A ninth insulating film INS9 may be disposed on the eighth insulating film INS8 and the eighth conductive layer ML8. The ninth insulating film INS9 may be formed of a silicon oxide (SiOₓ)-based inorganic film, but the embodiment is not limited thereto.

Each of the ninth vias VA9 may penetrate the ninth insulating film INS9 and be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via VA9 may be about 16500 Å.

The display element layer EML may be disposed on the light emitting element backplane EBP. The display element layer EML may include light emitting elements LE each including a reflective electrode layer RL, tenth and eleventh insulating films INS10 and INS11, a tenth via VA10, the first electrode AND, a light emitting stack ES, and a second electrode CAT; a pixel defining film PDL; and a plurality of trenches TRC.

The reflective electrode layer RL may be disposed on the ninth insulating film INS9. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 6.

Each of the first reflective electrodes RL1 may be disposed on the ninth insulating film INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

Each of the second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

Each of the third reflective electrodes RL3 may be disposed on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

The fourth reflective electrodes RL4 may be respectively disposed on the third reflective electrodes RL3. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the fourth reflective electrodes RL4 may include titanium (Ti).

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be about 100 Å, and the thickness of the second reflective electrode RL2 may be about 850 Å.

A tenth insulating film INS10 may be disposed on the ninth insulating film INS9. The tenth insulating film INS10 may be disposed between the reflective electrode layers RL adjacent to each other in a horizontal direction. The tenth insulating film INS10 may be disposed on the reflective electrode layer RL in the third pixel PX3. The tenth insulating film INS10 may be formed of a silicon oxide (SiOₓ)-based inorganic film, but the embodiment is not limited thereto.

An eleventh insulating film INSI1 may be disposed on the tenth insulating film INS10 and the reflective electrode layer RL. The eleventh insulating film INS11 may be formed of a silicon oxide (SiOₓ)-based inorganic film, but the embodiment is not limited thereto. The tenth insulating film INS10 and the eleventh insulating film INS11 may be an optical auxiliary layer through which light reflected by the reflective electrode layer RL passes, among light emitted from the light emitting elements LE.

In order to match the resonance distance of the light emitted from the light emitting elements LE in at least one of the first pixel PX1, the second pixel PX2, or the third pixel PX3, the tenth insulating film INS10 and the eleventh insulating film INSI1 may not be disposed under or below the first electrode AND of the first pixel PX1. The first electrode AND of the first pixel PX1 may be directly disposed on the reflective electrode layer RL. The eleventh insulating film INS11 may be disposed under or below the first electrode AND of the second pixel PX2. The tenth insulating film INS10 and the eleventh insulating film INSI1 may be disposed under or below the first electrode AND of the third pixel PX3.

In summary, the distance between the first electrode AND and the reflective electrode layer RL may be different in the first pixel PX1, the second pixel PX2, and the third pixel PX3. In order to adjust the distance from the reflective electrode layer RL to the second electrode CAT according to the main wavelength of the light emitted from each of the first pixel PX1, the second pixel PX2, and the third pixel PX3, the presence or absence of the tenth insulating film INS10 and the eleventh insulating film INSI1 may be set in each of the first pixel PX1, the second pixel PX2, and the third pixel PX3. For example, it is illustrated in FIG. 6 that the distance between the first electrode AND and the reflective electrode layer RL in the third pixel PX3 is larger than the distance between the first electrode AND and the reflective electrode layer RL in the second pixel PX2 and the distance between the first electrode AND and the reflective electrode layer RL in the first pixel PX1, and the distance between the first electrode AND and the reflective electrode layer RL in the second pixel PX2 is larger than the distance between the first electrode AND and the reflective electrode layer RL in the first pixel PX1, but the specification is not limited thereto.

Although the tenth insulating film INS10 and the eleventh insulating film INS11 are illustrated in the embodiment, a twelfth insulating film disposed under or below the first electrode AND of the first pixel PX1 may be added. For example, the eleventh insulating film INS11 and the twelfth insulating film INS12 may be disposed under or below the first electrode AND of the second pixel PX2, and the tenth insulating film INS10, the eleventh insulating film INS11, and the twelfth insulating film INS12 may be disposed under or below the first electrode AND of the third pixel PX3.

Each of the tenth vias VA10 may penetrate the tenth insulating film INS10 and/or the eleventh insulating film INS11 in the second pixel PX2 and the third pixel PX3 and may be connected to the exposed ninth conductive layer ML9. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the second pixel PX2 may be smaller than the thickness of the tenth via VA10 in the third pixel PX3.

The first electrode AND of each of the light emitting elements LE may be disposed on the tenth insulating film INS10 and connected to the tenth via VA10. The first electrode AND of each of the light emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

The pixel defining film PDL may be disposed on a portion of the first electrode AND of each of the light emitting elements LE. The pixel defining film PDL may cover the edge of the first electrode AND of each of the light emitting elements LE. The pixel defining film PDL may serve to partition the first emission areas EA1, the second emission areas EA2, and the third emission areas EA3.

The first emission area EA1 may be defined as an area in which the first electrode AND, the light emitting stack ES, and the second electrode CAT may be sequentially stacked each other in the first pixel PX1 to emit light. The second emission area EA2 may be defined as an area in which the first electrode AND, the light emitting stack ES, and the second electrode CAT may be sequentially stacked each other in the second pixel PX2 to emit light. The third emission area EA3 may be defined as an area in which the first electrode AND, the light emitting stack ES, and the second electrode CAT may be sequentially stacked each other in the third pixel PX3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOₓ)-based inorganic film, but the embodiment is not limited thereto. The first pixel defining film PDL1, the second pixel defining film PDL2, and the third pixel defining film PDL3 may each have a thickness of about 500 Å.

In case that the first pixel defining film PDL1, the second pixel defining film PDL2, and the third pixel defining film PDL3 are formed as one pixel defining film, the height of the one pixel defining film increases, so that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to prevent the first encapsulation inorganic film TFE1 from being cut off due to the step coverage, the first pixel defining film PDL1, the second pixel defining film PDL2, and the third pixel defining film PDL3 may have a cross-sectional structure having a stepped portion. For example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. The width of the first pixel defining film PDL1 refers to the horizontal length of the first pixel defining film PDL1 defined in the first direction DR1 and the second direction DR2.

Each of the plurality of trenches TRC may penetrate the first pixel defining film PDL1, the second pixel defining film PDL2, and the third pixel defining film PDL3. Furthermore, each of the plurality of trenches TRC may penetrate the eleventh insulating film INS11. The tenth insulating film INS10 may be partially recessed at each of the plurality of trenches TRC.

At least one trench TRC may be disposed between adjacent pixels PX1, PX2, and PX3.

Although FIG. 6 illustrates that two trenches TRC are disposed between adjacent pixels PX1, PX2, and PX3, the embodiment is not limited thereto.

The light emitting stack ES may include a plurality of intermediate layers. FIG. 6 illustrates that the light emitting stack ES has a three-tandem structure including a first stack layer IL1, a second stack layer IL2, and a third stack layer IL3, but the embodiment is not limited thereto. For example, the light emitting stack ES may have a two-tandem structure including two intermediate layers.

In the three-tandem structure, the light emitting stack ES may have a tandem structure including a plurality of stack layers IL1, IL2, and IL3 that emit different lights. For example, the light emitting stack ES may include the first stack layer IL1 that emits light of the first color, the second stack layer IL2 that emits light of the second color, and the third stack layer IL3 that emits light of the third color. The first stack layer IL1, the second stack layer IL2, and the third stack layer IL3 may be sequentially stacked each other.

The first stack layer IL1 may have a structure in which a first hole transport layer, a first organic light emitting layer that emits light of the first color, and a first electron transport layer are sequentially stacked each other. The second stack layer IL2 may have a structure in which a second hole transport layer, a second organic light emitting layer that emits light of the second color, and a second electron transport layer are sequentially stacked each other. The third stack layer IL3 may have a structure in which a third hole transport layer, a third organic light emitting layer that emits light of the third color, and a third electron transport layer may be sequentially stacked each other. For example, the light emitting stack may emit white light in which the light of the first color (for example, red light) from the first organic light emitting layer, the light of the second color (for example, green light) from the second organic light emitting layer, and the light of the third color (for example, blue light) from the third organic light emitting layer are mixed. Accordingly, the white light may be emitted from each of the first emission area EA1, the second emission area EA2, and the third emission area EA3. Here, the white light having passed through the first emission area EA1 may be incident on a first color filter CF1, the white light having passed through the second emission area EA2 may be incident on a second color filter CF2, and the white light having passed through the third emission area EA3 may be incident on a third color filter CF3.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and may be disposed on the bottom surface of each trench TRC. Due to the trench TRC, the first stack layer IL1 may be separated between adjacent pixels PX1, PX2, and PX3. The second stack layer IL2 may be disposed on the first stack layer IL1. Due to the trench TRC, the second stack layer IL2 may be separated between adjacent pixels PX1, PX2, and PX3. A cavity ESS or an empty space may be disposed between the first stack layer IL1 and the second stack layer IL2. The third stack layer IL3 may be disposed on the second stack layer IL2. The third stack layer IL3 is not cut off by the trench TRC and may be disposed to cover the second stack layer IL2 in each of the trenches TRC. For example, in the three-tandem structure, each of the plurality of trenches TRC may be a structure for cutting off the first to second stack layers IL1 and IL2, the first charge generation layer, and the second charge generation layer of the display element layer EML between the pixels PX1, PX2, and PX3 adjacent to each other. In the two-tandem structure, each of the trenches TRC may be a structure for cutting off the charge generation layer disposed between a lower intermediate layer and an upper intermediate layer, and the lower intermediate layer.

In order to stably cut off the first and second stack layers IL1 and IL2 of the display element layer EML between adjacent pixels PX1, PX2, and PX3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the first to third stack layers IL1, IL2, and IL3 of the display element layer EML between the neighboring pixels PX1, PX2, and PX3, another structure may exist instead of the trench TRC. For example, instead of the trench TRC, a reverse tapered partition wall may be disposed on the pixel defining film PDL.

The number of the stack layers IL1, IL2, and IL3 that emit different lights is not limited to that shown in FIG. 6. For example, the light emitting stack ES may include two intermediate layers. For example, one of the two intermediate layers may be substantially the same as the first stack layer IL1, and the other may include a second hole transport layer, a second organic light emitting layer, a third organic light emitting layer, and a second electron transport layer. For example, a charge generation layer for supplying electrons to one intermediate layer and supplying charges to the other intermediate layer may be disposed between the two intermediate layers.

FIG. 6 illustrates that the first to third stack layers IL1, IL2, and IL3 are all disposed in the first emission area EA1, the second emission area EA2, and the third emission area EA3, but the embodiment is not limited thereto. For example, the first stack layer IL1 may be disposed in the first emission area EA1, and may not be disposed in the second emission area EA2 and the third emission area EA3. Furthermore, the second stack layer IL2 may be disposed in the second emission area EA2 and may not be disposed in the first emission area EA1 and the third emission area EA3. Further, the third stack layer IL3 may be disposed in the third emission area EA3 and may not be disposed in the first emission area EA1 and the second emission area EA2. For example, first to third color filters CF1, CF2, and CF3 of the optical layer OPL may be omitted.

The second electrode CAT may be disposed on the third stack layer IL3. The second electrode CAT may be disposed on the third stack layer IL3 in each of the plurality of trenches TRC. The second electrode CAT may be formed of a transparent conductive material (TCO) such as ITO or IZO that can transmit light or a semi-transmissive conductive material such as magnesium (Mg), silver (Ag), or an alloy of Mg and Ag. In case that the second electrode CAT is formed of a semi-transmissive conductive material, the light emission efficiency may be improved in each of the first to third pixels PX1, PX2, and PX3 due to a micro-cavity effect.

The encapsulation layer TFE may be disposed on the display element layer EML. The encapsulation layer TFE may include at least one inorganic film TFE1 and TFE2 to prevent oxygen or moisture from permeating into the display element layer EML. For example, the encapsulation layer TFE may include the first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer in which one or more inorganic films selected from silicon nitride (SiNₓ), silicon oxynitride (SiOₓN_{y}), and silicon oxide (SiOₓ) may be alternately stacked each other. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed of titanium oxide (TiOₓ) or aluminum oxide (AlOₓ), but an embodiment is not limited thereto. The second encapsulation inorganic film TFE2 may be formed by an atomic layer deposition (ALD) process. The thickness of the second encapsulation inorganic film TFE2 may be smaller than the thickness of the first encapsulation inorganic film TFE1.

An organic film APL may be a layer for increasing the interfacial adhesion between the encapsulation layer TFE and the optical layer OPL. The organic film APL may be an organic film such as acrylic resin, epoxy resin, phenolic resin, polyamide resin, or polyimide resin.

The optical layer OPL may include a color filter layer CFL, a lens layer LSL, a filling layer FIL, a cover layer CVL, a retardation layer QWP, and a wire grid polarizer WGP.

The color filter layer CFL may include the plurality of color filters CF1, CF2, and CF3. The plurality of color filters CF1, CF2, and CF3 may include the first to third color filters CF1, CF2, and CF3. The first to third color filters CF1, CF2, and CF3 may be disposed on an organic film APL.

The first color filter CF1 may overlap the first emission area EA1 (for example, red light emission area) of the first pixel PX1. The first color filter CF1 may transmit light of the first color, for example, light of a red wavelength band. The red wavelength band may be in a range of about 600 nm to about 750 nm. Thus, the first color filter CF1 may transmit light of the first color among light emitted from the first emission area EA1.

The second color filter CF2 may overlap the second emission area EA2 (for example, green light emission area) of the second pixel PX2. The second color filter CF2 may transmit light of the second color, for example, light of a green wavelength band. The green wavelength band may be in a range of about 480 nm to about 560 nm. Thus, the second color filter CF2 may transmit light of the second color among light emitted from the second emission area EA2.

The third color filter CF3 may overlap the third emission area EA3 (for example, blue light emission area) of the third pixel PX3. The third color filter CF3 may transmit light of the third color, for example, light of a blue wavelength band. The blue wavelength band may be in a range of about 370 nm to about 460 nm. Thus, the first color filter CF1 may transmit light of the first color among light emitted from the first emission area EA1.

A planarization layer PLL may be disposed on the color filter layer CFL. The planarization layer PLL may function to planarize the stepped portion at the lower portion. The planarization layer PLL may be an organic film such as acrylic resin, epoxy resin, phenolic resin, polyamide resin, or polyimide resin.

The lens layer LSL may be disposed on the planarization layer PLL. The lens layer LSL may include the plurality of lenses LNS. The plurality of lenses LNS may be disposed on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction.

The filling layer FIL may be disposed on the lens layer LSL. For example, the filling layer FIL may be disposed on the plurality of lenses LNS. The filling layer FIL may have a selectable refractive index such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be disposed on the filling layer FIL. The cover layer CVL may be a glass substrate or a polymer resin. The cover layer CVL may be a glass substrate or a polymer resin. In case that the cover layer CVL is a glass substrate, it may be attached onto the filling layer FIL. For example, the filling layer FIL may serve to bond the cover layer CVL. In case that the cover layer CVL is a glass substrate, it may serve as an encapsulation substrate. In case that the cover layer CVL is a polymer resin, it may be directly applied onto the filling layer FIL.

The retardation layer QWP (or retardation plate, or retardation film) may be disposed on the color filter layer CFL. For example, the retardation layer QWP may be disposed between the color filter layer CFL and the wire grid polarizer WGP. The retardation layer QWP may be a V/4 plate (quarter-wave plate), but the embodiment is not limited thereto. The retardation layer QWP may be formed, for example, by a coating method.

In an embodiment, the retardation layer QWP may include an alignment film ALL, a liquid crystal layer LC disposed on the alignment film ALL, and a capping layer CPL disposed on the liquid crystal layer LC. The alignment film ALL may function to align the liquid crystal layer LC disposed on the alignment film ALL. For example, the alignment film ALL has reactions such as photoisomerization and photocrosslinking that occur anisotropically in case that irradiated with polarized light, and thus anisotropy may be generated on the polymer surface, which may induce the molecular arrangement of the liquid crystal in one direction or in a direction. The liquid crystal layer LC may be formed by coating a liquid crystal material including reactive mesogen (RM) to be aligned on the alignment film ALL and polymerizing them.

The capping layer CPL functions to protect the liquid crystal layer LC. The capping layer CPL may include an inorganic insulating material. For example, the capping layer CPL may include any one material of silicon nitride (SiNₓ), silicon oxynitride (SiOₓN_{y}), and silicon oxide (SiOₓ). The capping layer CPL may have a selectable thickness, for example, a thickness in a range of about 50 to about 1000 nm, to protect the liquid crystal layer LC. In an embodiment, the capping layer CPL may have a thickness in a range of about 100 to about 500 nm.

The wire grid polarizer WGP may be disposed on the retardation layer QWP, may be disposed, for example, between the retardation layer QWP and the planarization layer PLL.

The wire grid polarizer WGP and the retardation layer QWP may constitute a polarization member. For example, the polarization member according to an embodiment may include the retardation layer QWP and the wire grid polarizer WGP.

The wire grid polarizer WGP may include a plurality of wire grid patterns GP. As shown in FIG. 5, each wire grid pattern GP may have a rectangular shape extending along the second direction DR2. Further, as shown in FIG. 5, the wire grid patterns GP may be arranged or disposed along the first direction DR1. The wire grid patterns GP may be disposed to be spaced apart from each other in the first direction DR1.

The wire grid polarizer WGP may transmit light of a given polarization direction while reflecting light of another polarization direction to recycle it. This wire grid polarizer WGP is useful as a reflective polarizer because it exhibits higher polarization separation performance than other polarizers. For example, the wire grid polarizer WGP may be a device that creates polarization using a conductive wire grid, and may have a structure in which a plurality of wires made of a conductive material are periodically arranged or disposed in parallel to each other in a nano size on the retardation layer QWP to form the grid patterns GP.

In the wire grid polarizer WGP including the plurality of wire grid patterns GP, if the period of the wire grid pattern GP is less than the wavelength of the incident light, diffraction of the incident light does not occur. Thus, the wire grid polarizer WGP may transmit, among the incident light, a component having a vibration direction orthogonal to the conductive wire grid pattern GP, such as transverse magnetic (TM) polarization (for example, a P wave), while reflecting a component having a vibration direction parallel to the wire grid pattern GP, such as transverse electric (TE) polarization (for example, a S wave). In other words, in case that the arrangement period of the wire grid pattern GP is shorter than the wavelength of the electromagnetic wave incident on the wire grid polarizer WGP, the wire grid polarizer WGP may reflect a polarization component (for example, S wave) parallel to the wire grid pattern GP, while transmitting a polarization component (for example, P wave) orthogonal to the wire grid pattern GP. Since the wire grid polarizer WGP uses the wire grid pattern GP made of metal, light reflection efficiency thereof is very high. Thus, as the reflected light can be re-reflected, the light can be recycled to make all lights into one polarized light.

The wire grid patterns GP may be disposed to be spaced apart from each other by a first pitch P1 in the first direction DR1. The first pitch P1 may be a distance between the centers of the wire grid patterns GP adjacent to each other. The first pitch P1 of the wire grid pattern GP may be in a range of about 50 to about 150 nm. In an embodiment, the first pitch P1 of the wire grid pattern GP may be in a range of about 50 to about 100 nm. The first pitch P1 of the wire grid patterns GP may be the same in all the wire grid patterns GP, or some may be different from each other.

The wire grid patterns GP may be disposed to be spaced apart from each other in the first direction DR1 with a separation distance equal to a second pitch P2. The second pitch P2 may be a distance between side edges of the wire grid patterns GP adjacent to each other. The second pitch P2 of the wire grid pattern GP may be in a range of about 40 to about 100 nm. In an embodiment, the second pitch P2 of the wire grid pattern GP may be in a range of about 40 to about 50 nm. The second pitch P2 of the wire grid pattern GP may be the same in all the wire grid patterns GP, or some may be different from each other.

The wire grid pattern GP may have a selectable thickness in consideration of process properties, reflection characteristics, or the like A thickness TK1 of the wire grid pattern GP may be in a range of about 10 to about 1000 nm. In an embodiment, the thickness TK1 of the wire grid pattern GP may be in a range of about 100 to about 300 nm. The thickness TK1 of the wire grid patterns GP may be the same in all the wire grid patterns GP, or some may be different from each other.

The wire grid pattern GP may include a grid pattern GPL and a metal pattern MPL.

The grid pattern GPL may form the upper layer of the wire grid pattern GP and may substantially perform the function of the wire grid pattern GP. The grid pattern GPL may be disposed between the metal pattern MPL and the planarization layer PLL. The grid pattern GPL may include a material with high reflectivity to perform the light reflection function described above. For example, the grid pattern GPL may include at least one of aluminum (Al), silver (Ag), or gold (Au). A thickness TK2 of the grid pattern GPL may be in a range of about 10 to about 1000 nm.

The metal pattern MPL may form the lower layer of the wire grid pattern GP and may function to adhere to the retardation layer QWP disposed thereunder. The metal pattern MPL may be disposed between the wire grid pattern GP and the capping layer CPL of the retardation layer QWP. The metal pattern MPL may be disposed directly on the capping layer CPL of the retardation layer QWP to improve adhesive strength between the wire grid pattern GP and the capping layer CPL.

As in the embodiment described later, in case that the grid pattern GPL is disposed directly on the capping layer CPL, the adhesive strength with the capping layer CPL is relatively weak, so that problems such as lifting of the film may occur in the subsequent process. In the disclosure, the adhesive strength of the wire grid pattern GP may be improved by disposing the metal pattern MPL between the grid pattern GPL and the capping layer CPL.

The metal pattern MPL may include a material with excellent adhesive strength with the capping layer CPL, for example, an inorganic insulating material. For example, the metal pattern MPL may include any one of titanium (Ti), chromium (Cr), nickel (Ni), tantalum (Ta), and tungsten (W). A thickness TK3 of the metal pattern MPL may be in a range of about 1 to about 1000 nm. In an embodiment, the thickness TK3 of the metal pattern MPL may be in a range of about 3 to about 7 nm in consideration of adhesive strength, reliability, and transmittance.

The wire grid polarizer WGP may include an air layer AIL. The air layer AIL may be disposed between the wire grid patterns GP. By way of example, the air layer AIL may be disposed in an area partitioned by the capping layer CPL, the wire grid patterns GP, and the planarization layer PLL. The air layer AIL may be disposed between the wire grid patterns GP and extend in the second direction DR2 in parallel with the wire grid patterns GP. The air layers AIL may be disposed to be spaced apart from each other in the first direction DR1 with the wire grid pattern GP disposed between the air layers AIL. The air layer AIL may act as a path through which light emitted from the internal light emitting stack ES is transmitted.

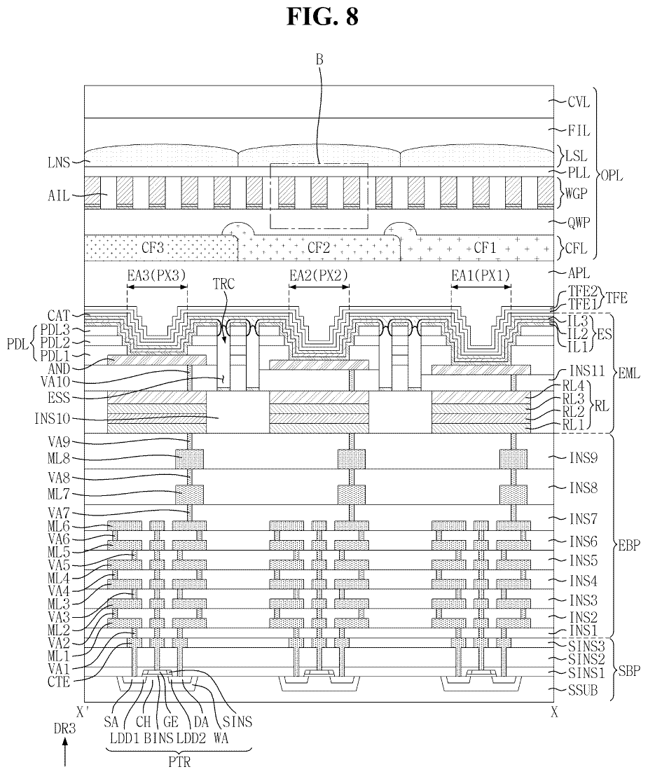

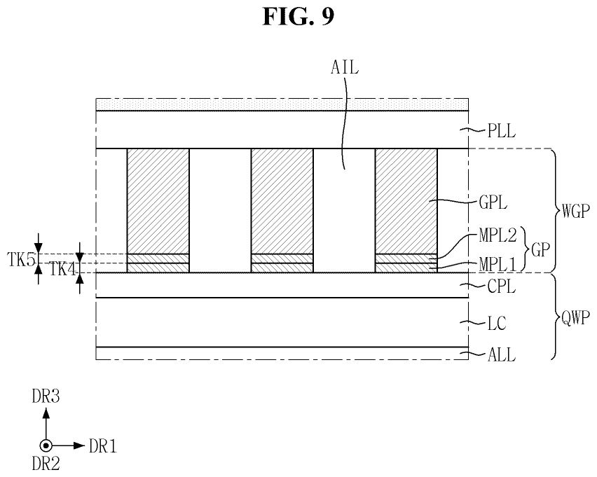

FIG. 8 is a schematic cross-sectional view showing another example of a display panel according to an embodiment. FIG. 9 is an enlarged schematic view of area B of FIG. 8.

Referring to FIGS. 8 and 9, according to an embodiment, the wire grid polarizer WGP may include a plurality of metal patterns MPL1 and MPL2, which is different from the embodiment of FIGS. 6 and 7 described above. In the following description, redundant description of the above-described embodiments will be omitted while focusing on differences.

Referring to FIGS. 8 and 9, the wire grid polarizer WGP may include the plurality of metal patterns MPL1 and MPL2 in the wire grid pattern GP. The plurality of metal patterns MPL1 and MPL2 may include the first metal pattern MPL1 and the second metal pattern MPL2.

The first metal pattern MPL1 may form the lowermost layer of the wire grid pattern GP and may function to adhere to the retardation layer QWP disposed thereunder. The first metal pattern MPL1 may be disposed between the second metal pattern MPL2 and the capping layer CPL of the retardation layer QWP. The first metal pattern MPL1 may be disposed directly on the capping layer CPL of the retardation layer QWP to improve adhesive strength between the wire grid pattern GP and the capping layer CPL.

The first metal pattern MPL1 may include a material with excellent adhesive strength with the capping layer CPL, for example, an inorganic insulating material. The first metal pattern MPL1 may include a material with excellent adhesive strength with the second metal pattern MPL2. For example, the first metal pattern MPL1 may include at least one of titanium (Ti), chromium (Cr), nickel (Ni), tantalum (Ta), or tungsten (W). A thickness TK4 of the first metal pattern MPL1 may be in a range of about 1 to about 1000 nm. In an embodiment, the thickness TK4 of the first metal pattern MPL1 may be in a range of about 3 to about 7 nm in consideration of adhesive strength, reliability, and transmittance.

The second metal pattern MPL2 may form the lower layer of the wire grid pattern GP and may function to adhere the first metal pattern MPL1 to the grid pattern GPL. The second metal pattern MPL2 may be disposed between the first metal pattern MPL1 and the grid pattern GPL. The second metal pattern MPL2 may be disposed directly on the first metal pattern MPL1 to improve adhesive strength between the grid pattern GPL and the first metal pattern MPL1.

The second metal pattern MPL2 may include a material with excellent adhesive strength with the grid pattern GPL and the first metal pattern MPL1. For example, the second metal pattern MPL2 may include at least one of titanium (Ti), chromium (Cr), nickel (Ni), tantalum (Ta), or tungsten (W). A thickness TK5 of the first metal pattern MPL2 may be in a range of about 1 to about 1000 nm. In an embodiment, the thickness TK5 of the second metal pattern MPL2 may be in a range of about 3 to about 7 nm in consideration of adhesive strength, reliability, and transmittance.

According to an embodiment, the first metal pattern MPL1 and the second metal pattern MPL2 may include different materials. Each of the first metal pattern MPL1 and the second metal pattern MPL2 may be selected from titanium (Ti), chromium (Cr), nickel (Ni), tantalum (Ta), and tungsten (W), but may include different materials. For example, in case that the first metal pattern MPL1 may include titanium (Ti), the second metal pattern MPL2 may include chromium (Cr). In an embodiment, in case that the first metal pattern MPL1 may include chromium (Cr), the second metal pattern MPL2 may include titanium (Ti).

The thickness TK4 of the first metal pattern MPL1 and the thickness TK5 of the second metal pattern MPL2 may be different from each other. For example, the thickness TK4 of the first metal pattern MPL1 may be greater than the thickness TK5 of the second metal pattern MPL2. The first metal pattern MPL1 may substantially perform a function having adhesive strength with the capping layer CPL, and by forming the thickness TK4 of the first metal pattern MPL1 to be greater than the thickness TK5 of the second metal pattern MPL2, this may further contribute to improving the adhesive strength between the wire grid pattern GP and the capping layer CPL.

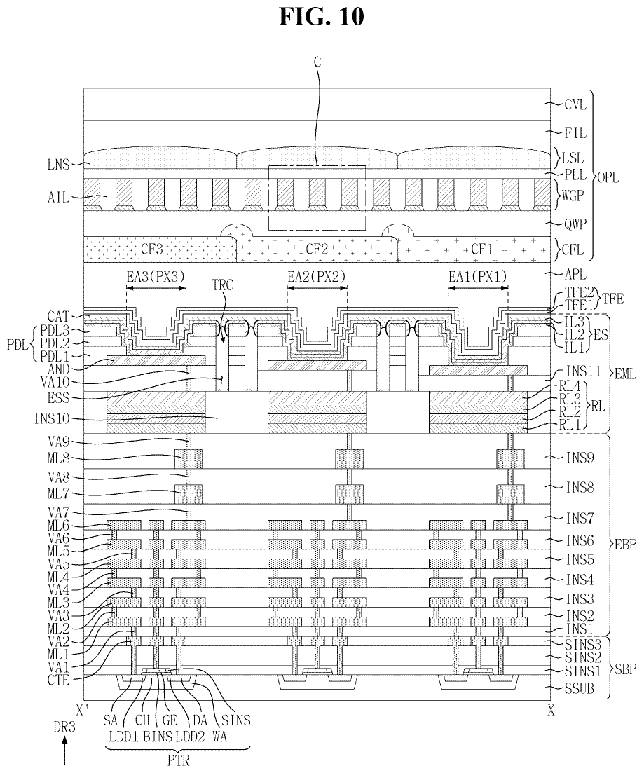

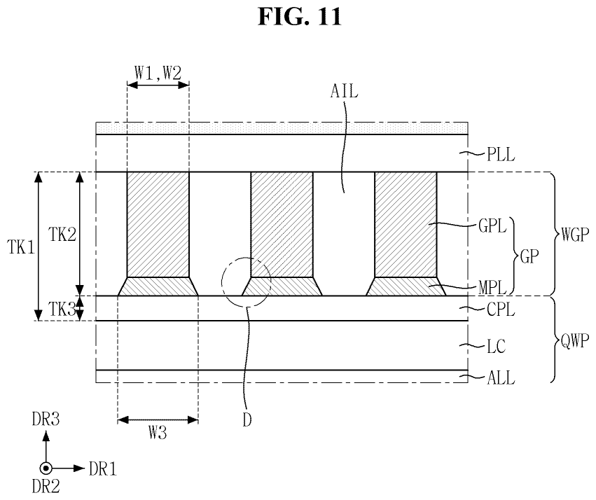

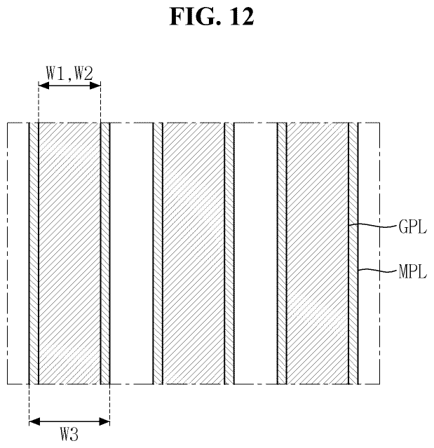

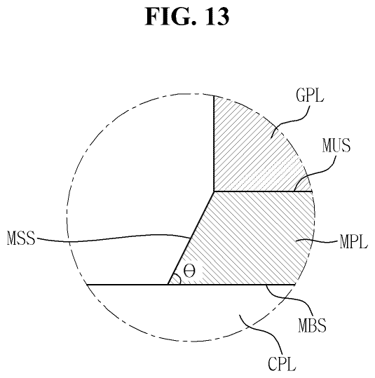

FIG. 10 is a schematic cross-sectional view showing another example of a display panel according to an embodiment. FIG. 11 is an enlarged schematic view of area C of FIG. 10. FIG. 12 is a schematic plan view schematically showing a wire grid pattern. FIG. 13 is an enlarged schematic view of area D of FIG. 11.

Referring to FIGS. 10 to 13, according to an embodiment, the width of the metal pattern MPL is larger than the width of the grid pattern GPL, which is different from the embodiment of FIGS. 6 and 7 described above.

The wire grid polarizer WGP may include the wire grid pattern GP, and the wire grid pattern GP may include the grid pattern GPL and the metal pattern MPL.

The grid pattern GPL may have a width W1 in consideration of light transmittance, reflectivity, or the like within the spirit and the scope of the disclosure. The width W1 of the grid pattern GPL may be in a range of about 1 to about 100 nm.

The metal pattern MPL may be disposed between the grid pattern GPL and the capping layer CPL. The metal pattern MPL may include a top surface MUS in contact with the grid pattern GPL, a bottom surface MBS in contact with the capping layer CPL, and a side surface MSS connecting the top surface MUS to the bottom surface MBS.

A width W2 of the top surface MUS of the metal pattern MPL may be the same as the width W1 of the grid pattern GPL. A width W3 of the bottom surface MBS of the metal pattern MPL may be greater than the width W2 of the top surface MUS of the metal pattern MPL. For example, the width W3 of the bottom surface MBS of the metal pattern MPL may be larger than the width W1 of the grid pattern GPL. As described above, the metal pattern MPL is intended to improve adhesive strength with the capping layer CPL, and in case that the width of the bottom surface MBS of the metal pattern MPL in contact with the capping layer CPL is large, adhesive strength with the capping layer CPL may be increased.

In an embodiment, the width of the metal pattern MPL may gradually increase from the top surface MUS to the bottom surface MBS of the metal pattern MPL. For example, the width of the metal pattern MPL may gradually increase as it is closer to the retardation layer QWP.

The side surface MSS of the metal pattern MPL may have an inclination. An interior angle θ formed between the side surface MSS of the metal pattern MPL and the bottom surface MBS of the metal pattern MPL may be greater than or equal to about 60 degrees and less than about 90 degrees. In case that the interior angle θ formed between the side surface MSS of the metal pattern MPL and the bottom surface MBS of the metal pattern MPL is within the above range, the adhesive strength between the capping layer CPL and the wire grid pattern GP may be improved, and the transmittance may be prevented from decreasing.

In the embodiment, by forming the width W2 of the bottom surface MBS of the metal pattern MPL to be larger than the width W1 of the grid pattern GPL, the adhesive strength with the capping layer CPL may be further improved.

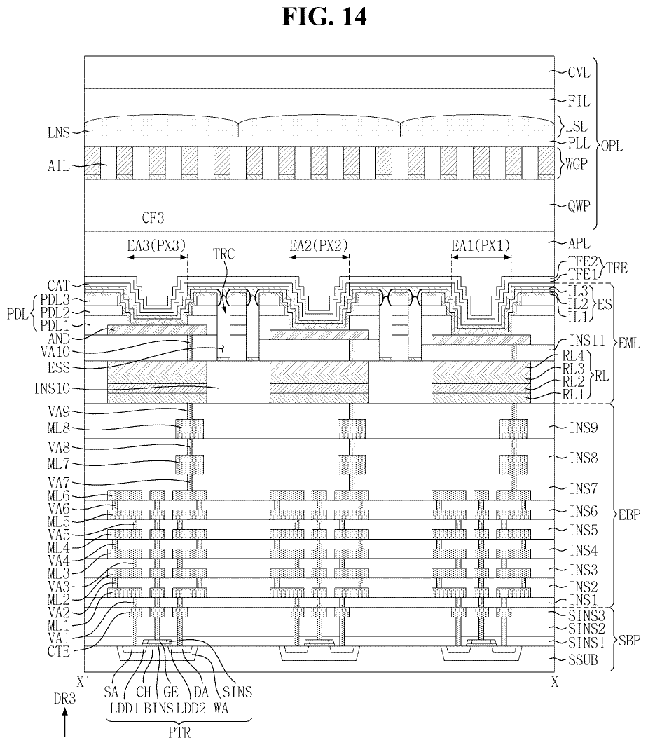

FIG. 14 is a schematic cross-sectional view showing an example of a display panel according to an embodiment.

The display device of FIG. 14 is different from the above-described display device of FIG. 6 in that the color filter layer CFL described above in FIG. 6 is not included.

For example, the display panel 100 of FIG. 6 may be a “white-OLED” type display panel in which the light emitting stacks ES of the pixels PX1, PX2, and PX3 included in the unit pixel UPX all provide white light, whereas the display panel 100 of FIG. 14 to be described later may be a “RGB-OLED” type display panel in which the light emitting stacks ES of the pixels PX1, PX2, and PX3 included in the unit pixel UPX provide red light, green light, and blue light, respectively.

As shown in FIG. 14, since the display panel 100 does not include the color filter layer CFL, the organic film APL and the retardation layer QWP may be in contact with each other.

According to an embodiment, the light emitting stack ES of FIG. 14 may provide light of different colors for each pixel. For example, the light emitting stack ES of the first pixel PX1 may include a red organic light emitting layer that provides red light, the light emitting stack ES of the second pixel PX2 may include a green organic light emitting layer that provides green light, and the light emitting stack ES of the third pixel PX3 may include a blue organic light emitting layer that provides blue light. In other words, the light emitting stack ES may include the red organic light emitting layer described above in the first emission area EA1 of the first pixel PX1, the green organic light emitting layer described above in the second emission area EA2 of the second pixel PX2, and the blue organic light emitting layer described above in the third emission area EA3 of the third pixel PX3. Accordingly, the first pixel PX1 may provide red light generated by the red organic light emitting layer, the second pixel PX2 may provide green light generated by the green organic light emitting layer, and the third pixel PX3 may provide blue light generated by the blue organic light emitting layer.

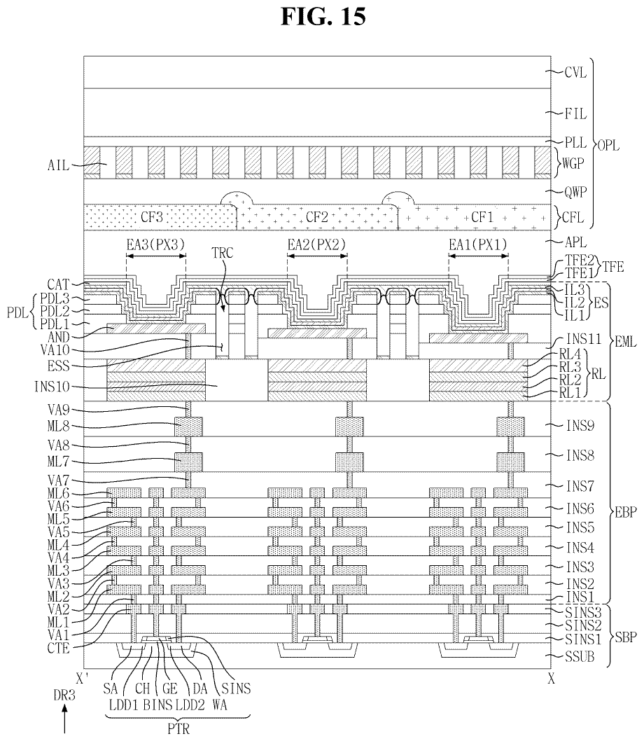

FIG. 15 is a schematic cross-sectional view showing an example of a display panel according to an embodiment.

The display device of FIG. 15 is different from the display device of FIG. 6 described above in that the lens layer LSL described above is not included.

As illustrated in FIG. 15, since the display panel 100 does not include the lens layer LSL described above, the planarization layer PLL and the filling layer FIL may be in contact with each other.

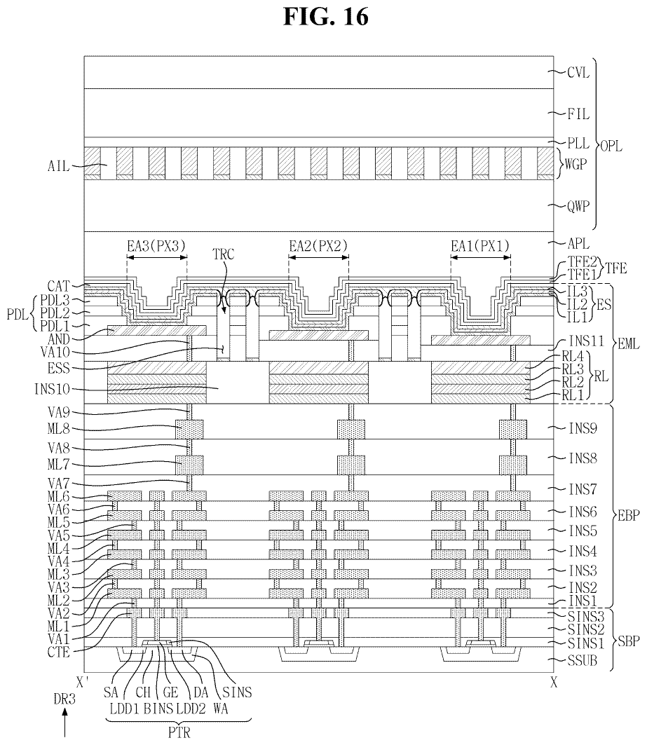

FIG. 16 is a schematic cross-sectional view showing an example of a display panel according to an embodiment.

The display device of FIG. 16 is different from the display device of FIG. 6 described above in that the color filter layer CFL and lens layer LSL described above are not included.

As illustrated in FIG. 16, since the display panel 100 does not include the color filter layer CFL and lens layer LSL described above, the planarization layer PLL may be in contact with the filling layer FIL.

In the experimental example disclosed below, a crosscut adhesive strength test and transmittance were measured to determine the adhesive strength between the silicon nitride layer and the titanium layer.

### Comparative Example 1

A sample substrate was manufactured by sequentially stacking a silicon nitride (SiNₓ) layer with a thickness of about 300 nm, an aluminum (Al) layer with a thickness of about 200 nm, and a silicon oxynitride (SiOₓN_{y}) layer with a thickness of about 100 nm on a glass substrate.

### Example 1

In Comparative Example 1, a sample substrate was manufactured by additionally stacking a titanium (Ti) layer with a thickness of about 5 nm between the silicon nitride layer and the aluminum layer.

### Example 2

In Example 1, sample substrates were manufactured with titanium (Ti) layers with different thicknesses of about 1 nm, about 2 nm, about 3 nm, about 7 nm, about 10 nm, and about 15 nm, respectively.

A crosscut adhesive strength test was performed on the sample substrates manufactured in Comparative Example 1, Example 1, and Example 2, respectively, and the transmittances of the sample substrates manufactured in Example 1 and Example 2 were measured. In the crosscut adhesive strength test, the sample substrate was crosscut in a 90-degree direction using a fork according to ASTM standards, and a tape was attached to the surface of the sample substrate and detached.

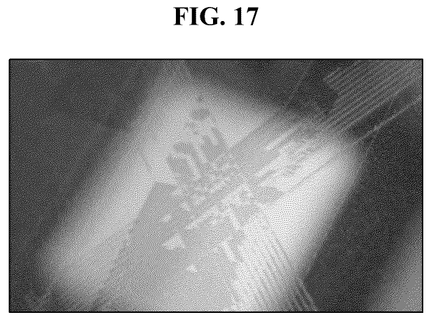

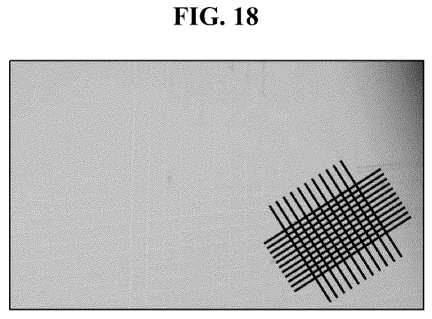

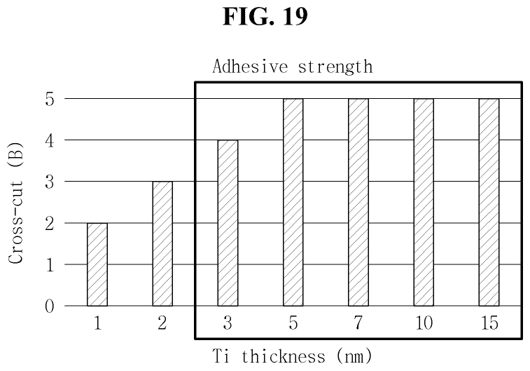

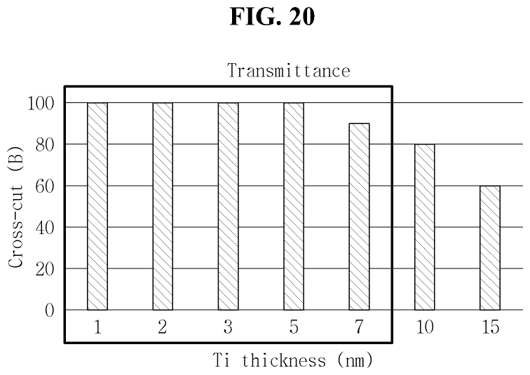

FIG. 17 is an image of the substrate after the crosscut adhesive strength test according to Comparative Example 1. FIG. 18 is an image of the substrate after the crosscut adhesive strength test according to Example 1. FIG. 19 is a graph illustrating the crosscut adhesive strength according to the thickness of the titanium layer. FIG. 20 is a graph illustrating the transmittance of the substrate according to the thickness of the titanium layer.

Referring to FIG. 17, the sample substrate in which the silicon nitride layer and the aluminum layer were in direct contact according to Comparative Example 1 showed a lot of the film was detached, and the crosscut adhesive strength test result value is GB. On the other hand, referring to FIG. 18, the sample substrate in which the silicon nitride layer and the titanium layer were in direct contact according to Example 1 showed the film was not detached, and the crosscut adhesive strength test result value is 5B.

Referring to FIG. 19, as the thickness of the titanium layer increased, the crosscut adhesive strength test result value increased, and in case that the thickness of the titanium layer was greater than or equal to 5 in a range of about nm, the same 5B value was shown.

Referring to FIG. 20, the transmittance was 100% in case that the titanium layer had a thickness in a range of about of 1 to about 5 nm, about 90% at about 7 nm, about 80% at about 10 nm, and about 60% at about 15 nm.

Through these results, it was confirmed that the adhesive strength of the sample substrate was improved in case that the titanium layer was inserted between the silicon nitride layer and the aluminum layer. It may be seen that the adhesive strength between the silicon nitride layer and the titanium layer is excellent. By way of example, in the disclosure, it was confirmed that in case that the thickness of the titanium layer was formed in the range of about 3 to about 7 nm, it was possible to have the adhesive strength property of 5B or more and the transmittance of about 90% or more.

In the following, in the display panel 100 illustrated in FIGS. 6 and 7, the reliability test and transmittance of a case where the wire grid pattern GP may include only the grid pattern GPL and a case where the wire grid pattern GP may include the grid pattern GPL and the metal pattern MPL, were measured.

### Comparative Example 2

In the display panel illustrated in FIG. 6, the wire grid polarizer WGP was manufactured, and the display panel was manufactured while the components disposed above the wire grid polarizer WGP were omitted. At this time, the capping layer CPL of the retardation layer QWP was formed of silicon nitride (SiNₓ), and the wire grid pattern GP was formed to include only the grid pattern GPL of aluminum (Al).

### Example 3

In the same structure as Comparative Example 2, the display panel was manufactured differently such that the wire grid pattern GP may include the grid pattern GPL and the metal pattern MPL of titanium (Ti).

After silicon oxynitride was stacked on the wire grid pattern GP of each display panel manufactured according to Comparative Example 2 and Example 3, the display panel was observed.

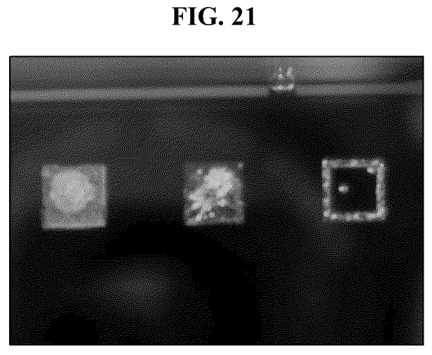

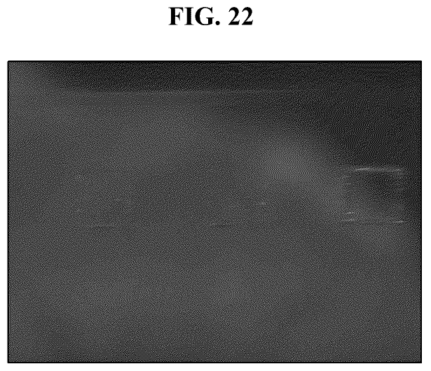

FIG. 21 is an image of a display panel manufactured according to Comparative Example 2. FIG. 22 is an image of a display panel manufactured according to Example 3.

Referring to FIG. 21, in the display panel according to Comparative Example 2, the aluminum grid pattern exhibited a film lifting off from the silicon nitride capping layer, and bubbles were generated.

On the other hand, referring to FIG. 22, in the display panel according to Example 3, the metal pattern of titanium did not exhibit a film lifting phenomenon off from the silicon nitride capping layer.

Through these results, it was confirmed that the adhesive strength between the capping layer of silicon nitride and the metal pattern of titanium of the wire grid pattern was excellent.

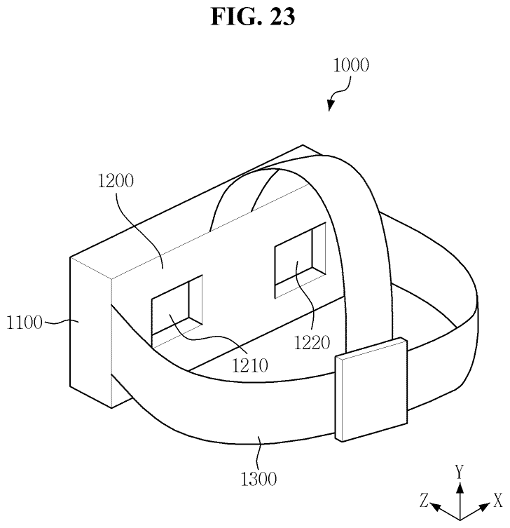

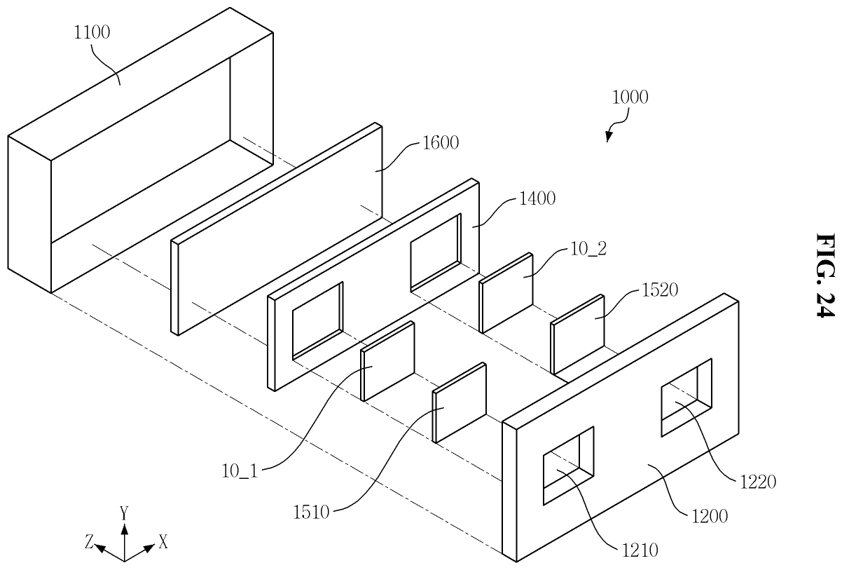

FIG. 23 is a schematic perspective view illustrating a head mounted display according to an embodiment. FIG. 24 is an exploded schematic perspective view illustrating an example of the head mounted display of FIG. 23.

Referring to FIGS. 23 and 24, a head mounted display 1000 according to an embodiment may include a first display device 10_1, a second display device 102, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 may provide an image to the user's left eye, and the second display device 102 may provide an image to the user's right eye. Since each of the first display device 10_1 and the second display device 10_2 is substantially the same as the display device 10 described in conjunction with FIGS. 1 and 2, a description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 may serve or function to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. By way of example, the control circuit board 1600 may transmit the same digital video data DATA to the first display device 10_1 and the second display device 10_2.

The display device housing 1100 may serve or function to accommodate the first display device 10_1, the second display device 10_2, the middle frame 1400, the first optical member 1510, the second optical member 1520, and the control circuit board 1600. The housing cover 1200 may be disposed to cover one open surface of the display device housing 1100. The housing cover 1200 may include the first eyepiece 1210 at which the user's left eye is disposed and the second eyepiece 1220 at which the user's right eye is disposed. FIGS. 23 and 24 illustrate that the first eyepiece 1210 and the second eyepiece 1220 are disposed separately, but the embodiment is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

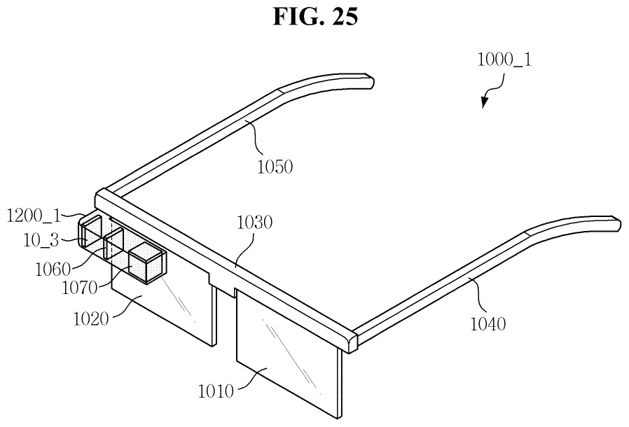

The head mounted band 1300 may serve or function to secure the display device housing 1100 to the user's head such that the first eyepiece 1210 and the second eyepiece 1220 of the housing cover 1200 remain disposed on the user's left and right eyes, respectively. In case that the display device housing 1200 is implemented to be lightweight and compact, the head mounted display 1000 may be provided with an eyeglass frame as shown in FIG. 25 instead of the head mounted band 1300.

The head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 25 is a schematic perspective view illustrating a head mounted display according to an embodiment.

Referring to FIG. 25, a head mounted display 1000_1 according to an embodiment may be an eyeglasses-type display device in which a display device housing 12001 is implemented in a lightweight and compact manner. The head mounted display 1000_1 according to an embodiment may include a display device 10_3, a left eye lens 1010, a right eye lens 1020, a support frame 1030, temples 1040 and 1050, an optical member 1060, an optical path changing member 1070, and the display device housing 1200_1.

The display device housing 12001 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 25 illustrates that the display device housing 1200_1 is disposed at the right end of the support frame 1030, but the embodiment is not limited thereto. For example, the display device housing 12001 may be disposed at the left end of the support frame 1030, and the image of the display device 103 may be provided to the user's left eye. By way of example, the display device housing 12001 may be disposed at both the left and right ends of the support frame 1030, and the user may view the image displayed on the display device 10_3 through both the left and right eyes.

In concluding the detailed description, those skilled in the art will appreciate that many variations and modifications can be made to the embodiments without substantially departing from the principles of the disclosure. Therefore, the disclosed embodiments are used in a generic and descriptive sense only and not for purposes of limitation.

What is claimed is:

1. A display device comprising:
a display element layer disposed on a substrate, the display element layer comprising a first electrode, a light emitting layer, and a second electrode;
a retardation layer disposed on the display element layer, the retardation layer comprising at least a capping layer; and
a wire grid polarizer disposed on the retardation layer, the wire grid polarizer comprising a wire grid pattern in which a metal pattern and a grid pattern are stacked each other,
wherein the metal pattern is disposed on the capping layer, and has a thickness in a range of about 3 nm to about 7 nm.

2. The display device of claim 1, wherein the capping layer includes any one of silicon nitride, silicon oxide, and silicon oxynitride.

3. The display device of claim 1, wherein the metal pattern includes any one of titanium (Ti), chromium (Cr), nickel (Ni), tantalum (Ta), and tungsten (W).

4. The display device of claim 1, wherein the grid pattern is disposed on the metal pattern, and a thickness of the grid pattern is greater than a thickness of the metal pattern.

5. The display device of claim 1, wherein a width of the grid pattern is equal to a width of the metal pattern.

6. The display device of claim 1, wherein a width of a bottom surface of the metal pattern is greater than a width of an upper surface of the metal pattern.

7. The display device of claim 6, wherein the width of the upper surface of the metal pattern is equal to a width of the grid pattern.

8. The display device of claim 1, wherein a width of the metal pattern gradually increases from an upper surface to a lower surface of the metal pattern.

9. The display device of claim 1, wherein
a side surface of the metal pattern has an inclination, and
an interior angle formed between the side surface of the metal pattern and a lower surface of the metal pattern is greater than or equal to about 60 degrees and less than about 90 degrees.

10. The display device of claim 1, further comprising:
a planarization layer disposed on the wire grid polarizer,
wherein the wire grid polarizer comprises an air layer disposed in an area partitioned by the capping layer, the wire grid pattern, and the planarization layer.

11. A display device comprising:
a display element layer disposed on a substrate, the display element layer comprising a first electrode, a light emitting layer, and a second electrode;
a retardation layer disposed on the display element layer, the retardation layer comprising at least a capping layer; and
a wire grid polarizer disposed on the retardation layer, the wire grid polarizer comprising a wire grid pattern in which a first metal pattern, a second metal pattern, and a grid pattern are stacked each other, wherein
the first metal pattern is disposed on the capping layer,
the second metal pattern is disposed on the first metal pattern, and
the grid pattern is disposed on the second metal pattern.

12. The display device of claim 11, wherein the capping layer includes any one of silicon nitride, silicon oxide, or silicon oxynitride.

13. The display device of claim 11, wherein the first metal pattern and the second metal pattern include different materials.

14. The display device of claim 13, wherein each of the first metal pattern and the second metal pattern includes any one of titanium (Ti), chromium (Cr), nickel (Ni), tantalum (Ta), or tungsten (W).

15. The display device of claim 11, wherein a thickness of the first metal pattern and a thickness of the second metal pattern are different from each other.

16. The display device of claim 15, wherein the thickness of the first metal pattern is greater than the thickness of the second metal pattern.

17. An optical device comprising:
a display device; and
an optical path changing member disposed on the display device, wherein
the display device comprises:
a display element layer disposed on a substrate, the display element layer comprising a first electrode, a light emitting layer, and a second electrode;
a retardation layer disposed on the display element layer, the retardation layer comprising at least a capping layer; and
a wire grid polarizer disposed on the retardation layer, the wire grid polarizer comprising a wire grid pattern in which a metal pattern and a grid pattern are stacked each other, and
the metal pattern is disposed on the capping layer, and has a thickness in a range of about 3 nm to about 7 nm.

18. The optical device of claim 17, wherein the capping layer includes any one of silicon nitride, silicon oxide, or silicon oxynitride.

19. The optical device of claim 17, wherein a width of the metal pattern gradually increases from an upper surface to a lower surface of the metal pattern.

20. The optical device of claim 17, wherein
the metal pattern comprises a first metal pattern disposed on the capping layer and a second metal pattern disposed on the first metal pattern, and
the grid pattern is disposed on the second metal pattern.
